(19) United States
(12) Patent Application Publication
(10) Pub. No.: US 2012/0091999 A1
(43) Pub. Date: Apr. 19, 2012

(54) INSULATED PROBE PIN AND METHOD FOR FABRICATING THE SAME

(75) Inventors: Toshihiro Zushi, Arida-shi (JP); Kenji Kawamura, Amagasaki-shi (JP); Masayuki Ataka, Arida-shi (JP); Toyokazu Nagato, Amagasaki-shi (JP); Hiroyuki Kamibayashi, Arida-shi (JP)

(73) Assignee: MITSUBISHI CABLE INDUSTRIES, LTD., Tokyo (JP)

(21) Appl. No.: 13/274,676

(22) Filed: Oct. 17, 2011

(30) Foreign Application Priority Data
Oct. 18, 2010 (JP) 2010-233920

(51) Int. Cl. G01R 1/06

(52) U.S. Cl. 324/149

(57) ABSTRACT

An insulated probe pin 10 includes a conductor probe pin 11 and an insulator coating 12 covering a periphery of the conductor probe pin 10 such that a sensing-side end portion of the conductor probe pin 10 is exposed. An end portion 12a of the insulator coating 12 toward the sensing-side end of the conductor probe pin 11 has a thickness larger than that of an end portion of the insulator coating 12 toward a connection-side end of the conductor probe pin 11 in an entire periphery of the insulator coating 12.

### CROSS-REFERENCE TO RELATED APPLICATION

This application claims priority to Japanese Patent Application No. 2010-233920 filed on Oct. 18, 2010, the disclosure of which including the specification, the drawings, and the claims is hereby incorporated by reference in its entirety.

### BACKGROUND

The present disclosure relates to insulated probe pins and methods for fabricating the insulated probe pins.

In general, to inspect an electric component such as a circuit board or a semiconductor element, electrification is conducted by bringing the tip of a probe pin at the sensing-side end of an insulated probe pin of a prober into contact with an electrode or an electrode pad provided on the electrode component. The insulated probe pin has a metal probe pin generally having a structure in which a sensing-side end portion of the probe pin is exposed and the periphery of the other portion is covered with an insulator coating.

Japanese Utility Model Registration No. 3038114 shows that electrification is performed after immersion of a portion of a metal probe pin to a predetermined distance from the sensing-side end in an electrodeposition solution, thereby forming an insulator coating through electrodeposition coating.

Japanese Patent Publication No. 2010-107420 proposes the use of a suspension containing block copolymer polyimide as an electrodeposition solution for forming an insulator coating through electrodeposition coating of a metal probe pin.

### SUMMARY

An insulated probe pin in an aspect of the present disclosure includes:

a conductor probe pin; and

an insulator coating covering a periphery of the conductor probe pin such that a sensing-side end portion of the conductor probe pin is exposed, wherein

an end portion of the insulator coating toward the sensing-side end of the conductor probe pin has a thickness larger than that of an end portion of the insulator coating toward a connection-side end of the conductor probe pin in an entire periphery of the insulator coating.

In another aspect of the present disclosure, a method for fabricating an insulated probe pin including a conductor probe pin and an insulator coating covering a periphery of the conductor probe pin such that a sensing-side end portion of the conductor probe pin is exposed includes the steps of:

(a) preparing an electrode having a hole containing an electrodeposition solution; and

(b) immersing a portion of the conductor probe pin having a predetermined length from a connection-side end of the conductor probe pin in the electrodeposition solution contained in the hole of the electrode, and then performing electrification between the electrode and the conductor probe pin.

Features and benefits of the present disclosure will become apparent from the following description with reference to the drawings.

### BRIEF DESCRIPTION OF THE DRAWINGS

FIG. 1 is a side view illustrating an insulated probe pin according to an embodiment.

FIG. 2A is a cross-sectional view taken along line IIA-IIA in FIG. 1, and FIG. 2B is a cross-sectional view taken along line IIB-IIB in FIG. 1.

FIG. 3 is a cross-sectional view taken along line in FIG. 1.

FIG. 4 is an illustration of a state in which the insulated probe pin of the embodiment is used.

FIG. 5 is a perspective view illustrating electrodeposition coating apparatus.

FIG. 6 is an illustration of a state in which a probe pin is held by a pin holding member.

FIG. 7 is an illustration of a state in which the pin holding member at a standby position is attached to a vertical movement means.

FIG. 8 is a view illustrating a state in which the pin holding member is set at a processing position by the vertical movement means.

FIG. 9 is a view illustrating a state of electrodeposition coating.

### DETAILED DESCRIPTION

An embodiment of the present disclosure will be described hereinafter with reference to the drawings.

### (Insulated Probe Pin)

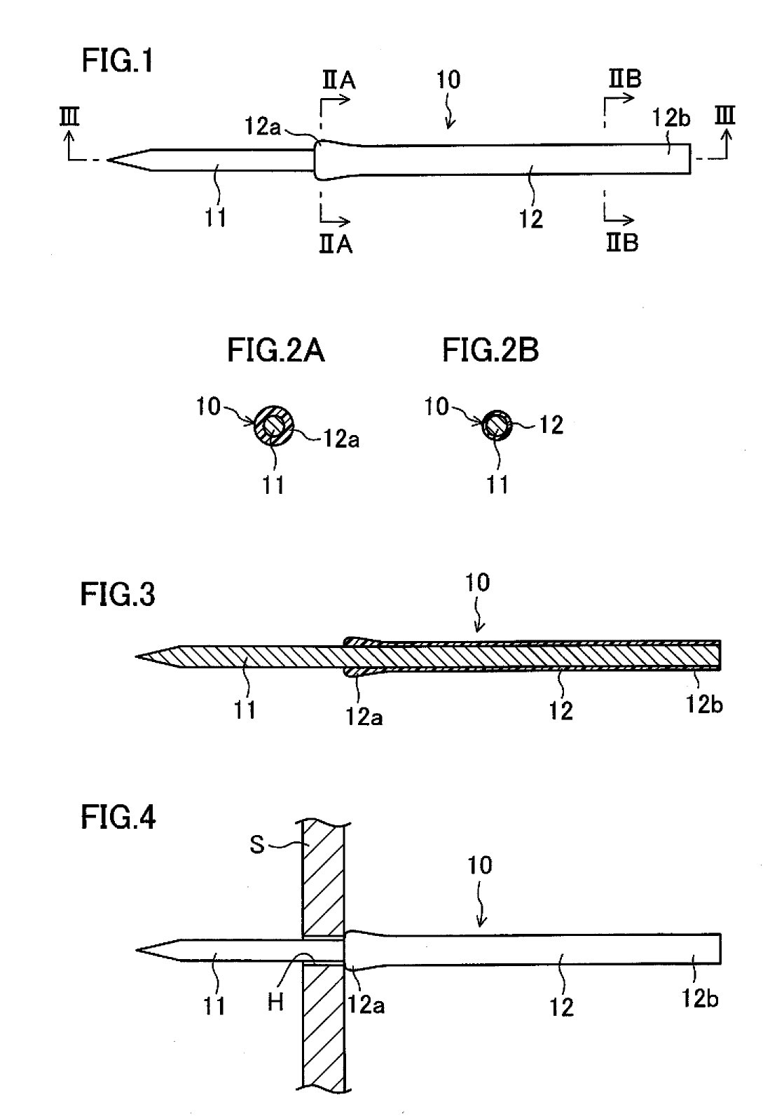

FIG. 1 illustrates an insulated probe pin 10 according to an embodiment. In the insulated probe pin 10 illustrated in FIG. 1, the left side corresponds to a sensing side, and the right side corresponds to a connection side. FIG. 2A is a cross-sectional view taken along line IIA-IIA in FIG. 1, and FIG. 2B is a cross-sectional view taken along line IIB-IIB in FIG. 1. FIG. 3 is a cross-sectional view taken along line in FIG. 1. The insulated probe pin 10 is, for example, a component attached to a prober for use in an inspection of an electric component such as a circuit board or a semiconductor element.

The insulated probe pin 10 includes a metal probe pin 11. A sensing-side end portion of the probe pin 11 is exposed, and the periphery of a portion of the probe pin 11 in the other end, i.e., a connection-side end portion, is covered with an insulator coating 12. In the connection-side end portion, the probe pin 11 may be exposed by peeling off the insulator coating 12 by optical peeling using, for example, a laser or chemical peeling using, for example, a solvent. The insulated probe pin 10 may be linear, or may be partially curved according to the application thereof. For example, the insulated probe pin 10 has a length of 10 mm to 150 mm and an outer diameter of 20 μm to 400 μm, and the probe pin 11 has an exposure length of 0.5 mm to 30 mm in the sensing-side end portion.

The probe pin 11 is made of a metal wire. The probe pin 11 preferably has a high conductivity and a high elasticity. The metal material for the probe pin 11 is not specifically limited, and may be copper, tungsten, rhenium-tungsten, or steel, for example. The probe pin 11 may be made of either a single metal material or an alloy of a plurality of metal materials. Examples of the alloy include beryllium copper having a high hardness and a high elasticity. The surface of the probe pin 11 may be plated with gold, for example. The cross sectional shape of the probe pin 11 may be circular or may be, for example, a polygon such as a rectangular. The tip of the sensing-side end portion of the probe pin 11 may be processed to be flat, round (spherical), pointed, triangular pyramidal, or in other shapes according to the type of an electrode or an electrode pad as an object. The probe pin 11 is not necessarily made of a metal, and may be made of any conductive material such as a conductive resin. The conductive resin only needs to have conductivity and elasticity required for the probe pin 11.

The insulator coating 12 is made of an insulating resin. The resin material for the insulator coating 12 is not specifically limited, and may be polyimide resin, acrylic resin, urethane resin, or epoxy resin, for example. The resin material for the insulator coating 12 is preferably polyimide resin including a siloxane bond in a molecular framework. The insulator coating 12 may be made of a single resin material, or may be made of a mixture of a plurality of resin materials.

The insulator coating 12 is uniformly attached to the entire periphery of the probe pin 11 such that the thickness of the attached insulator coating 12 is uniform without thickness deviation on any portion of the probe pin 11 along the length thereof. A portion 12b of the insulator coating 12 toward the connection-side end of the probe pin 11 has a uniform thickness of 1 μm to 50 μm, for example, along the length direction. An end portion 12a of the insulator coating 12 toward the sensing-side end is thicker than the connection-side end portion 12b of the insulator coating 12 in the entire periphery of the insulator coating 12. The maximum thickness of the sensing-side end portion 12a of the insulator coating 12 is 1.5 μm to 52.5 μm, for example, and is thicker than the thickness of the connection-side end portion of the insulator coating 12 by about 0.5 μm to about 2.5 μm, for example. The maximum thickness of the sensing-side end portion 12a of the insulator coating 12 is located at a distance of 0.02 mm to 1.5 mm, for example, and preferably at a distance of 0.02 mm to 0.5 mm, from the sensing-side end of the insulator coating 12.

In the insulated probe pin 10 of this embodiment, the sensing-side end portion 12a of the insulator coating 12 is thicker than the connection-side end portion 12b in the entire periphery. Thus, even in a case where a large number of insulated probe pins 10 are closely arranged in a prober, for example, the thick ends 12a of the insulator coatings 12 interfere with each other, and thus, the sensing-side exposed portions of the insulated probe pins 10 are less likely to come into contact with each other.

In addition, since the sensing-side end portion 12a of the insulator coating 12 is thicker than the connection-side end portion 12b in the entire periphery, even in such a case where a large number of insulated probe pins 10 are brought together, the thick sensing-side end portions 12a of the insulator coatings 12 provide appropriate spacing among the adjacent insulated probe pins 10. As a result, excellent handling can be obtained.

Furthermore, as an example of application of the insulated probe pin 10 of this embodiment, in a prober as illustrated in FIG. 4, the sensing-side exposed portion of the insulated probe pin 10 not covered with the insulator coating 12 projects through a probe hole H formed in a substrate S, and the sensing-side end portion 12a of the insulator coating 12 engages with the rim of the probe hole H when the insulator coating 12 projects therethrough. In this application, when an electrification test is conducted with the prober, an edge of the insulator coating is repeatedly subjected to stress, and moves back, thereby disadvantageously causing a variation in the amount of projection of the insulated probe pin from the probe hole. However, with the insulated probe pin 10 of this embodiment, since the sensing-side end portion 12a of the insulator coating 12 is thicker than the connection-side end portion 12b in the entire periphery, the insulator coating 12 can be reinforced. Accordingly, even when a large stress is applied upon contact with the rim of the probe hole H, cutting off or peeling of the sensing-side end portion 12a of the insulator coating 12 can be prevented, resulting in reduction of a variation in the amount of projection of the insulated probe pin 10 from the probe hole H. In addition, the product life of the insulated probe pin 10 can be prolonged. In terms of such reinforcement of the insulator coating 12, the insulator coating 12 preferably has a tapered portion whose thickness gradually decreases from the sensing-side end portion 12a toward the connection side, as illustrated in FIGS. 1 and 3. The insulator coating 12 may have a portion which is continuous to the connection-side end of the tapered portion and has a uniform thickness along the length direction. The distance from the thickest point of the sensing-side end portion 12a of the insulator coating 12 to the start end of the uniform-thickness portion of the insulator coating 12 is preferably in the range from 0.02 mm to 1.5 mm in terms of easiness of preventing a contact between the sensing-side exposed portions of the insulated probe pins 10.

### (Method for Fabricating Insulated Probe Pin)

The insulated probe pin 10 of this embodiment can be fabricated by preparing a probe pin 11 and electrodeposition coating apparatus 20 and performing electrodeposition coating on the probe pin 11 as follows.

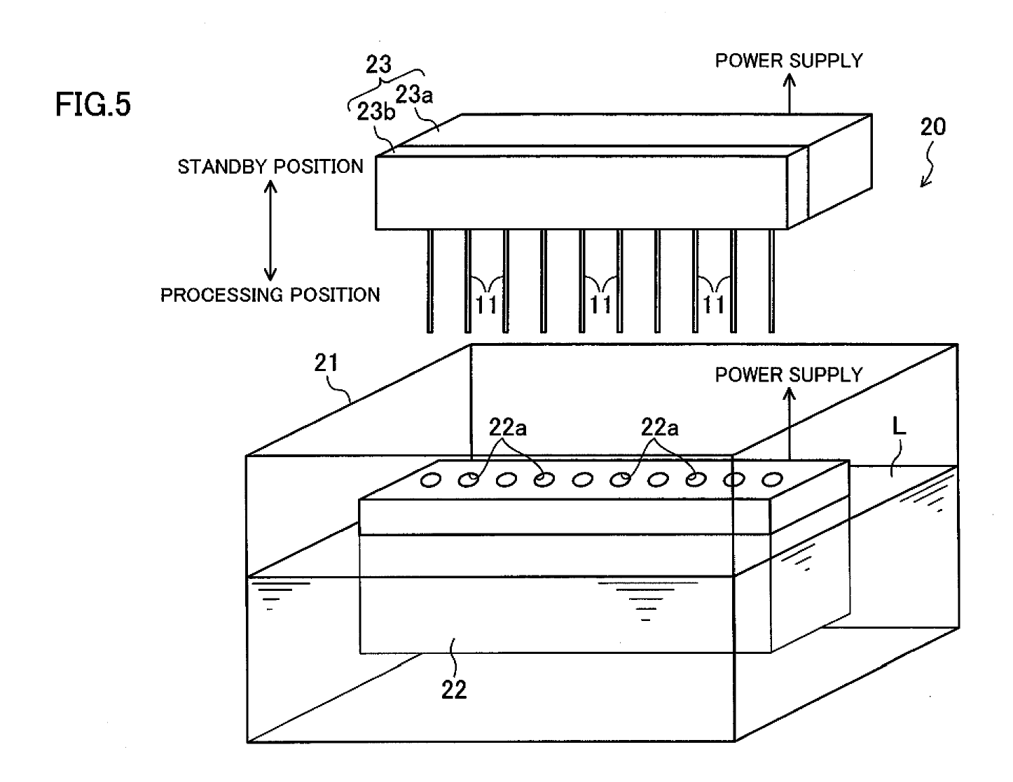

FIG. 5 illustrates electrodeposition coating apparatus 20.

The electrodeposition coating apparatus 20 includes an electrodeposition bath 21, a block-shape electrode 22, and a pin holding member 23.

The electrodeposition bath 21 is a container which is open at the top thereof, and is configured to contain an electrodeposition solution L.

The block-shape electrode 22 is placed in the electrodeposition bath 21 such that the top of the block-shape electrode 22 projects from the liquid surface of the electrodeposition solution L and the bottom thereof is not in contact with the bottom of the bath 21. In the block-shape electrode 22, a plurality of cylindrical holes 22a each vertically penetrating the block-shape electrode 22 are arranged in parallel. In this structure, the electrodeposition solution L flows into the cylindrical holes 22a to reach upper levels of the cylindrical holes 22a. The number of the cylindrical holes 22a is 1 to 50, for example. The diameter of each of the cylindrical holes 22a is 2 mm to 10 mm (preferably 3 mm to 8 mm), for example. The holes preferably have cylindrical shapes as the cylindrical holes 22a described above in terms of uniformity in thickness of the insulator coating 12 in a vertical cross section of the insulated probe pin 10. However, the present disclosure is not limited to this shape. As long as the holes are through holes, the shape of the holes may be, for example, a polygon such as a rectangular.

The block-shape electrode 22 may be made of a metal block. Alternatively, as long as at least the inner walls of the cylindrical holes 22a are made of a conductor such as a metal, the body of the block-shape electrode 22 may be made of an insulator, or may be made of a conductive porous material such that the inner walls of the cylindrical holes 22a are porous surfaces allowing the electrodeposition solution L to flow therethrough. Examples of the metal material for the block-shape electrode 22 include copper. The block-shape electrode 22 is connected to a power supply, which is not shown.

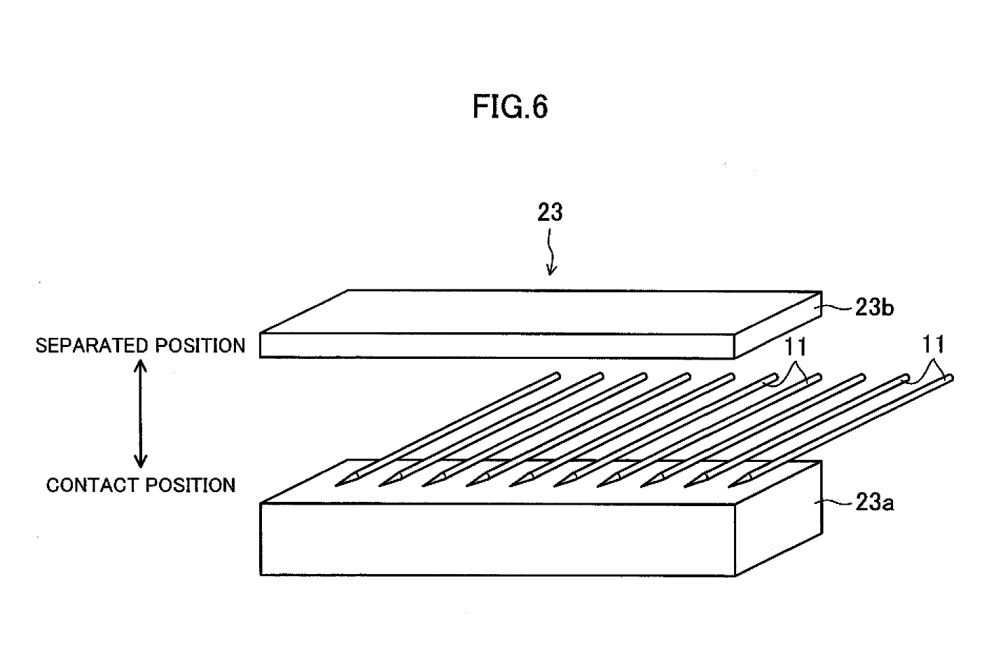

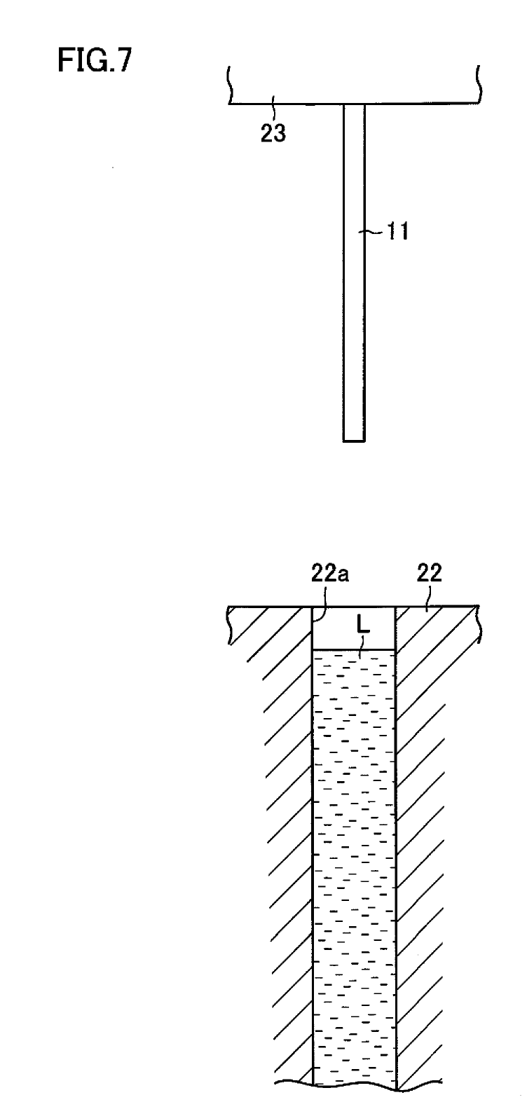

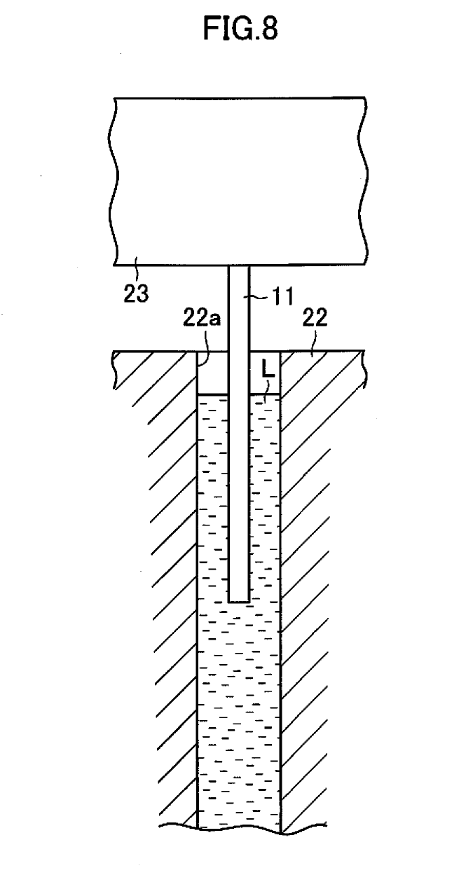

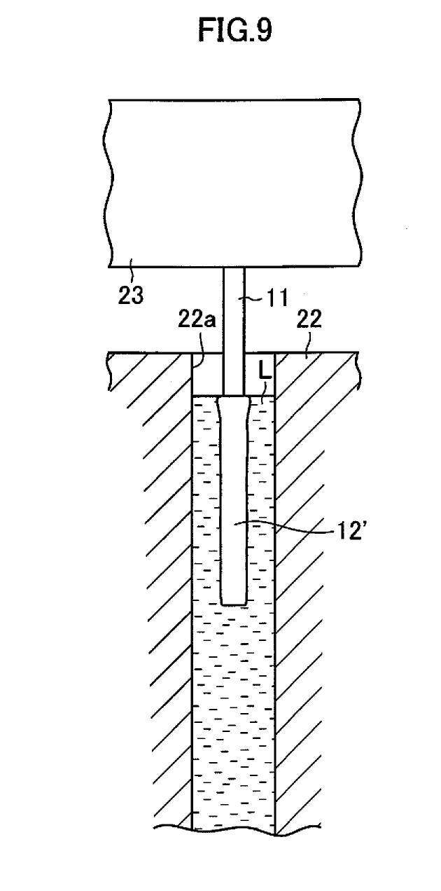

The pin holding member 23 is attached to a vertical movement means which is not shown and is located above the block-shape electrode 22 in the electrodeposition bath 21 such that the pin holding member 23 is movable between an upper standby position and a lower processing position. The pin holding member 23 has a member body 23a and a holding plate 23b, and is configured to be movable between a contact position at which the holding plate 23b is in contact with a side surface of the member body 23a and a separated position at which the holding plate 23b is separated from the side surface of the member body 23a. Accordingly, as illustrated in FIG. 6, a plurality of probe pins 11 are arranged in parallel at given intervals such that sensing-side end portions of the probe pins 11 are in contact with the side surface of the member body 23a with the holding plate 23b set at the separated position. When the holding plate 23b is set at the contact position, the sensing-side end portions of the probe pins 11 are held, while being arranged in parallel at given intervals. When the pin holding member 23 at the standby position is attached to the vertical movement means, while holding the probe pins 11, the probe pins 11 hang down and are located on the lines extended from the axes of the respective cylindrical holes 22a of the block-shape electrode 22, as shown in FIG. 7. Further, when the vertical movement means moves the pin holding member 23 from the standby position to the processing position, the probe pins 11 move vertically downward as shown in FIG. 8, resulting in that a portion of each of the probe pins 11 to a predetermined distance from the connection-side end is immersed in the electrodeposition solution L in an associated one of the cylindrical holes 22a of the block-shape electrode 22. In this structure, the number of the probe pins 11 which can be held by the pin holding member 23 is the same as the number of the cylindrical holes 22a of the block-shape electrode 22, and the pitch of the probe pins 11 to be held by the pin holding member 23 is the same as the pitch of the cylindrical holes 22a of the block-shape electrode 22. Examples of the metal material for the pin holding member 23 include stainless. The pin holding member 23 also serves as an electrode for electrification to the probe pins 11, and is connected to a power supply, which is not shown. As another embodiment, the probe pins 11 may be connected to the power supply to serve as separate electrodes.

As long as the electrodeposition solution L used in fabrication of the insulated probe pin 10 is a conductive solution containing a resin component, the resin component may be dissolved, emulsified, or suspended in the solution. However, the electrodeposition solution L is preferably a suspension in which the average particle size of the resin component is 0.1 μm or more in terms of a high electrodeposition efficiency, and is more preferably a suspension in which the average particle size of the resin component is 10 μm or less in terms of uniformity in thickness of the insulator coating 12. The average particle size here can be measured based on a particle size distribution in the electrodeposition solution L obtained with a Flow Particle Image Analyzer FPIA-3000S (produced by SYSMEX CORPORATION).

The resin component may be polymer or a polymer precursor. The resin component may have an anionic group such as a carboxyl group, a sulfonic acid group, or a phosphoric acid group, or may have a cationic group such as an organic ammonium group or a pyridium group. If the resin component has an anionic group, the pin holding member 23 holding the probe pins 11 serves as a positive electrode, and the block-shape electrode 22 serves as a negative electrode. On the other hand, if the resin component has a cationic group, the pin holding member 23 holding the probe pins 11 serves as a negative electrode, and the block-shape electrode 22 serves as a positive electrode. Examples of the resin component include acrylic resin, polyimide resin, urethane resin, and epoxy resin.

The electrodeposition solution L may contain water, an aqueous or oleaginous organic solvent, a pigment, a levelling agent, a dispersing agent, and/or an antifoaming agent, for example.

The conductivity of the electrodeposition solution L is in the range from 1.5 to 15 mS/m, for example, and is preferably in the range from 2.5 to 5 mS/m. The pH of the electrodeposition solution L is in the range from 6 to 9, for example, and is preferably in the range from 6.5 to 7.5. The viscosity of the electrodeposition solution L is in the range from 1 to 30 mPa·s, for example, and is preferably in the range from 1 to 10 mPa·s. The surface tension of the electrodeposition solution L is in the range from 10 to 70 mN/m, for example, and is preferably in the range from 20 to 40 mN/m. The solid content of the electrodeposition solution L is preferably in the range from 1 to 20 mass %, for example, and is preferably in the range from 3 to 10 mass %. The temperature of the electrodeposition solution L is in the range from 5 to 50° C., for example, and is preferably in the range from 10 to 30° C.

In performing electrodeposition coating on the probe pins 11, first, the pin holding member 23 at the standby position is removed from the vertical movement means. Then, as shown in FIG. 6, in the pin holding member 23, the holding plate 23b is set at the separated position, and the probe pins 11 are arranged in parallel at given intervals such that sensing-side end portions of the probe pins 11 are in contact with a side surface of the member body 23a. Then, the holding plate 23b is set at the contact position. At this time, the sensing-side end portions of the probe pins 11 are held by the pin holding member 23, while being arranged in parallel at given intervals. The tips of the sensing-side end portions of the probe pins 11 may be processed before or after electrodeposition of the insulator coating 12.

Next, as illustrated in FIG. 7, the pin holding member 23 is attached to the vertical movement means. At this time, the pin holding member 23 is set at the standby position, and the probe pins 11 hang down and are located on the lines extended from the axes of the respective cylindrical holes 22a of the block-shape electrode 22.

Then, as illustrated in FIG. 8, the vertical movement means is operated to set the pin holding member 23 at the processing position. At this time, the probe pins 11 move vertically downward, and a portion of each of the probe pins 11 to a predetermined distance from the connection-side ends is immersed in the electrodeposition solution L in an associated one of the cylindrical holes 22a of the block-shape electrode 22.

Thereafter, a voltage is applied between the block-shape electrode 22 and the pin holding member 23 for a predetermined period. The applied voltage is in the range from 5 V to 200 V, for example, and is preferably in the range from 40 V to 80 V. The period in which the voltage is applied is in the range from 1 (one) second to 180 seconds, for example, and is preferably in the range from 1 (one) second to 30 seconds. At this time, a potential difference occurs between the block-shape electrode 22 and the probe pins 11 held by the pin holding member 23 through the electrodeposition solution L, and a coating film 12′ of a resin component is deposited on portions of the probe pins 11 immersed in the electrodeposition solution L. In fabrication of the insulated probe pins 10 of this embodiment, the probe pins 11 are located on the axes of the respective cylindrical holes 22a of the block-shape electrode 22, and are immersed in the electrodeposition solution L. Accordingly, the outer peripheries of the probe pins 11 are at the same potential, resulting in deposition of the coating film 12′ with a uniform thickness along the entire periphery of each of the probe pins 11 without thickness deviation. In a case where a plurality of probe pins arranged in parallel are immersed in an electrodeposition solution, coating films deposited on some of the probe pins at both ends thereof have thicknesses larger than those of coating films deposited on other probe pins at an intermediate position because of the influence among the probe pins in some cases. However, in fabrication of the insulated probe pins 10 of this embodiment, since the probe pins 11 are immersed in the electrodeposition solution L in the respective cylindrical holes 22a, the influence among the probe pins 11 is eliminated, resulting in reduction of variation in thickness of the insulator coating 12 in a cross section of each of the resultant insulated probe pins 10. Further, the exposed lengths of the sensing-side end portions of the probe pins 11 are identical, resulting in reduction of variation in quality among the insulated probe pins 10.

Subsequently, the vertical movement means is operated to set the pin holding member 23 at the standby position. At this time, in terms of reduction of hanging down of the coating film 12′, the elevating speed of the vertical movement means is preferably in the range from 0.5 to 300 mm/s, and is more preferably in the range from 1 to 10 mm/s. Then, the pin holding member 23 is removed from the vertical movement means, and dried in a drying oven such that water or an organic solvent evaporates, and when necessary, baking is performed with a baking oven. In this manner, an insulator coating 12 is formed, and insulated probe pins 10 according to this embodiment are fabricated. Each of the insulated probe pins 10 is immersed in the electrodeposition solution L in an associated one of the cylindrical holes 22a, and is subjected to electrodeposition coating. Accordingly, the sensing-side end portion 12a of the insulator coating 12 near the liquid surface of the electrodeposition solution L has a thickness larger than that of the connection-side end portion 12b of the insulator coating 12 in the middle of the solution L. Thus, the insulator coating 12 has a tapered portion whose thickness gradually decreases from the end portion 12a toward the connection side.

In this embodiment, the insulator coating 12 is provided on the probe pin 11 by electrodeposition coating. However, the present disclosure is not limited to this process. Alternatively, the method of the present disclosure may employ a process in which an insulator coating film is provided on the probe pin to have its thickness varied along the length of the probe pin by so-called dipping, and then the insulator coating film is peeled off such that a thick portion of the insulator coating film is located at an end thereof and that a sensing-side end portion of the probe pin is exposed.

The foregoing embodiments are merely preferred examples in nature, and are not intended to limit the scope, applications, and use of the invention.

What is claimed is:

1. An insulated probe pin, comprising:
a conductor probe pin; and
an insulator coating covering a periphery of the conductor probe pin such that a sensing-side end portion of the conductor probe pin is exposed, wherein
an end portion of the insulator coating toward the sensing-side end of the conductor probe pin has a thickness larger than that of an end portion of the insulator coating toward a connection-side end of the conductor probe pin in an entire periphery of the insulator coating.

2. The insulated probe pin of claim 1, wherein the insulator coating has a tapered portion whose thickness gradually decreases from the sensing-side end portion toward the connection side.

3. The insulated probe pin of claim 2, wherein the insulator coating has a portion which is continuous to the connection-side end of the tapered portion and has a uniform thickness along a length direction.

4. The insulated probe pin of claim 3, wherein a distance from a thickest point of the sensing-side end portion of the insulator coating to a start end of the uniform-thickness portion of the insulator coating is in the range from 0.02 mm to 1.5 mm.

5. The insulated probe pin of claim 1, wherein the sensing-side end portion of the insulator coating is thicker than the connection-side end portion of the insulator coating by 0.5 μm to 2.5 μm.

6. The insulated probe pin of claim 1, wherein a thickest point of the sensing-side end portion of the insulator coating is located at a distance of 0.02 mm to 1.5 mm from the sensing-side end of the insulator coating.

7. The insulated probe pin of claim 1, wherein the probe pin is made of beryllium copper.

8. The insulated probe pin of claim 1, wherein the insulator coating is made of polyimide resin including a siloxane bond in a molecular framework.

9. A method for fabricating an insulated probe pin including a conductor probe pin and an insulator coating covering a periphery of the conductor probe pin such that a sensing-side end portion of the conductor probe pin is exposed, the method comprising the steps of:
(a) preparing an electrode having a hole containing an electrodeposition solution; and
(b) immersing a portion of the conductor probe pin having a predetermined length from a connection-side end of the conductor probe pin in the electrodeposition solution contained in the hole of the electrode, and then performing electrification between the electrode and the conductor probe pin.

10. The method of claim 9, wherein a plurality of holes are arranged in parallel in the electrode, and
the portion of the conductor probe pin having the predetermined length from the connection-side end of the conductor probe pin in the electrodeposition solution contained in each of the holes of the electrode.

11. The method of claim 9, wherein the electrodeposition solution is a suspension in which an average particle size of a resin component is in the range from 0.1 μm to 10 μm.

12. The method of claim 9, wherein the hole of the electrode is a cylindrical hole.
